(19) United States
(12) Patent Application Publication
(10) Pub. No.: US 2022/0282367 A1
(43) Pub. Date: Sep. 8, 2022

(54) FORMULATION FOR DEPOSITION OF SILICON DOPED HAFNIUM OXIDE

(71) Applicant: VERSUM MATERIALS US, LLC, TEMPE, AZ (US)

(72) Inventors: MATTHEW R. MACDONALD, MISSION VIEJO, CA (US); XINJIAN LEI, VISTA, CA (US); MOO-SUNG KIM, GYEONGGI-DO (KR); SE-WON LEE, GYEONGGI-DO (KR)

(73) Assignee: VERSUM MATERIALS US, LLC, TEMPE, AZ (US)

(21) Appl. No.: 17/641,280

(22) PCT Filed: Sep. 9, 2020
(86) PCT No.: PCT/US2020/049801

§ 371 Date: Mar. 8, 2022

Related U.S. Application Data
(60) Provisional application No. 62/898,781, filed on Sep. 11, 2019.

(51) Int. Cl. C23C 16/40; C23C 16/455

(52) U.S. Cl. CPC C23C 16/405; C23C 16/45553

(57) ABSTRACT

In one aspect, the invention is formulations comprising both organoaminohafnium and organoaminosilane precursor compounds that allow anchoring both silicon-containing fragments and hafnium-containing fragments onto a given surface having hydroxyl groups to deposit silicon doped hafnium oxide having a silicon doping level ranging from about 3 to about 5 mol. %, suitable for forming a ferroelectric material. In another aspect, the invention is methods and systems for depositing the silicon doped hafnium oxide films suitable for forming ferroelectric materials using the formulations.

### CROSS-REFERENCE TO RELATED APPLICATIONS

This application is the 371 U.S. National Stage entry of International Application No. PCT/US2020/049801, filed Sep. 9, 2020, which claims benefit of U.S. Provisional Application No. 62/898,781 filed on Sep. 11, 2019. The disclosure of those applications is hereby incorporated by reference in their entirety.

### FIELD OF THE INVENTION

The invention relates to new formulations which can be used to deposit silicon doped hafnium oxide as ferroelectric materials for future memory applications.

### BACKGROUND OF THE INVENTION

Described herein are novel formulations or compositions (they are exchangeable), methods, and systems comprising same to deposit silicon doped hafnium oxide via a thermal atomic layer deposition (ALD) or plasma enhanced atomic layer deposition (PEALD) process, cyclic chemical vapor deposition, plasma enhanced cyclic chemical vapor deposition or a combination thereof.

More specifically, described herein is a composition, method and systems for formation of a silicon doped hafnium oxide having a silicon doping level ranging from about 2 to about 6 mol. %, preferably about 3.00 to about 5.00 mol. %, at one or more deposition temperatures of about 350° C. or less including, for example, from about 200° C. to about 350° C.

Atomic Layer Deposition (ALD) and Plasma Enhanced Atomic Layer Deposition (PEALD) are current processes used to deposit silicon doped hafnium oxide employing super cycle approaches, i.e. many cycles of hafnium oxide followed by one or a few cycles of silicon oxide to control the amount of silicon dopant to provide ferroelectric material upon annealing the resulting nanolaminates to crystallize into orthorhombic phase.

In both ALD and PEALD processes, the precursors and reactive gas (such as oxygen, oxygen plasma, ozone, or water) are separately pulsed in certain number of cycles to form multiple layers of hafnium oxide and a monolayer of silicon oxide at each super cycle. However, the silicon dopants may not homogenously distribute into the crystal lattice, which may be detrimental in the performance of ferroelectric materials in semiconductor applications. To remedy this, one possible solution is to co-deposit both silicon oxide and hafnium oxide at each ALD or PEALD cycle, allowing better inter-mixing of silicon and hafnium atoms, followed by thermal annealing to crystalize into proper orthorhombic phase suitable as ferroelectric material.

Examples of known precursors and methods are disclosed in the following publications, patents, and patent applications.

Claudia Richter, M. H. P., Tony Schenk, Robin Materlik, Christopher Kuenneth, Alfred Kersch, Cheol Seong Hwang, Thomas Mikolajick, Uwe Schroeder (2016). Impact of ALD processing on non-volatile memory performance of ferroelectric HfO₂ based capacitors. 16th International Conference on Atomic Layer Deposition. 24-27 Jul. 2016, Dublin, Ireland.

Recently, the ferroelectric behavior of thin doped hafnium oxide films caused by a non centrosymmetric orthorhombic phase was reported [Boescke, T. S., Mueller, J., Braeuhaus, D., Schroeder, U. and Boettger, U. (2011). “ferroelectricity in hafnium oxide thin films.” Appl. Phys. Lett. 99(10): 102903/102901-102903/102903.].

In the following years, novel memory devices using HfO₂ as a non-volatile storage layer were proposed. Continuous research was ongoing to understand the root cause of this so far unknown phase. Accordingly, the ferroelectric properties and crystal structure of doped HfO₂ thin films were investigated. After implementation of doped HfO₂ in a ferroelectric random access memory (FRAM) capacitor, important parameters for non-volatile data storage were characterized: e.g. remanent polarization, wake-up performance, endurance, fatigue and imprint together with typical dielectric properties like leakage current and dielectric constant. Ferroelectric Si doped HfO₂ films were processed by pulsing a certain amount of SiOₓ subcycles (silanediamine, N,N,N′,N′-tetraethyl/O₂ plasma) during HfO₂ deposition (tetrakis(ethylmethylamino)Hafnium/H₂O). The position of single SiOx subcycles was optimized. A distance of 21 HfO₂ cycles of the first SiOₓ layer to the bottom electrode led to an improvement in remanent and relaxed polarization (after 1 s) at similar wake-up behavior of the ferroelectric layer. In parallel, the cycling endurance could be increased by a factor of 10-100. SiO₂ or Al₂O₃ interlayers within the ferroelectric material could further improve the ferroelectric memory properties of the capacitor structure as long as the doped HfO₂ thickness was beyond a minimum thickness. Overall, results suggest a limited Si diffusion within the HfO₂ ab initio simulations confirmed the influence of doping distribution and oxygen vacancies on the phase stability of ferroelectric HfO even after a 1000° C. anneal

Hoffmann, M., Schroeder, U., Kuenneth, C., Kersch, A., Starschich, S., Boettger, U. and Mikolajick, T. (2015). “Ferroelectric phase transitions in nanoscale HfO₂ films enable giant pyroelectric energy conversion and highly efficient supercapacitors.” Nano Energy 18: 154-164. Temp.- and field-induced phase transitions in ferroelectric nanoscale TiN/Si:HfO₂/TiN capacitors with 3.8 to 5.6 mol. % Si content are investigated for energy conversion and storage applications. Films with 5.6 mol. % Si concentration exhibit an energy storage d. of ˜40 J/cm³ with a very high efficiency of ˜80% over a wide temp. range useful for supercapacitors. Furthermore, giant pyroelectric coefficients of up to −1300 μC/(m² K) are observed. due to temperature dependent ferroelectric to paraelectric phase transitions. The broad transition region is related to the grain size distribution and adjustable by the Si content. This strong pyroelectricity yields electrothermal coupling factors k₂ of up to 0.591 which are more than one order of magnitude higher than the best values ever reported. This enables pyroelectric energy harvesting with the highest harvestable energy d. ever reported of 20.27 J/cm³ per Olsen cycle. Possible applications in IR sensing are discussed. Inversely, through the electrocaloric effect an adiabatic temp. change of up to 9.5 K and the highest refrigerant capacity ever reported of 19.6 J/cm3 per cycle is achievable. This might enable energy efficient on-chip electrocaloric cooling devices. Addnl., low cost fabrication of these films is feasible by existing semiconductor process technol.

Mueller, S., Summerfelt, S. R., Mueller, J., Schroeder, U. and Mikolajick, T. (2012). “Ten-nanometer ferroelectric Si:HfO₂ films for next-generation FRAM capacitors.” IEEE Electron Device Lett. 33(9): 1300-1302.

Ferroelectric properties of Si-doped HfO₂ thin films (10 nm) have been investigated. The focus of this letter is to evaluate the potential applicability of these thin films for future 3-D ferroelectric random access memory capacitors. Polarization switching was tested at elevated temps. up to 185° C. and showed no severe degradation. Domain switching dynamics were elec. characterized with pulse-switching tests and were not in accordance with Kolmogorov-Avrami-type switching. Nucleation-limited switching is proposed to be applicable for these new types of ferroelectric thin films. Furthermore, same-state and opposite-state retention tests were performed at 125° C. up to 20 h. It was found that samples that had previously been annealed at 800° C. showed improved retention of the written state as well as of the opposite state. In addn., fatigue measurements were carried out, and no degradation occurred for 106 programming and erase cycles at 3 V.

Mueller, S. F., Yurchuk, E. and Schroeder, U. (2014)) “Ferroelectric memory cells for integrated circuits.” U.S. Pat. No. 9,053,802 B.

The integrated circuit includes a ferroelectric memory cell. The title ferroelectric memory cell includes a first oxide storage layer, a second oxide storage layer, and an amorphous layer disposed between the first and second oxide storage layers. Each of the first and second oxide storage layers includes a ferroelectric material that is at least partially in a ferroelectric state and further includes, as main components, oxygen and any of the group consisting of Hf, Zr and (Hf, Zr).

Park, J. U., Kim, J. Y., Cho, B. Y., Yoo, G. H., Chae, S. D., Kim, Y. S., Cho, Y. J., Choi, H. M. and Hwang, G. H. (2012)) “Organometallic compounds containing silylamines useful as precursors with good thermal stability for metal oxide or silicon-containing metal oxide deposition.” KR101284664 B1.

The invention relates to organometallic compounds having silylamine ligands (R¹R²N)₃-xM(L)(NR³SiR⁴R⁵R⁶)x, wherein M=Si, Ge, Ti, Zr, or Hf; L=halide, C1-6 alkyl, or cyclopentadienyl; R¹⁻⁶=independently H, C1-6 alkyl, or SiR¹²R¹³R¹⁴; R¹², R¹³, R¹⁴=independently H or C1-6 alkyl; and x=0, 1, 2, or 3.

Park, M. H., Lee, Y. H., Kim, H. J., Kim, Y. J., Moon, T., Kim, K. D., Mueller, J., Kersch, A., Schroeder, U., Mikolajick, T. and Hwang, C. S. (2015). “Ferroelectricity and Antiferroelectricity of Doped Thin HfO₂-Based Films.” Adv. Mater. (Weinheim, Ger.) 27(11): 1811-1831.

Park et al teaches the progress in ferroelectricity and antiferroelectricity in HfO₂-based thin films. Most ferroelectric thin film research focuses on perovskite structure materials, such as Pb(Zr,Ti)O₃, BaTiO₃, and SrBi₂Ta₂O₉, which are considered to be feasible candidate materials for nonvolatile semiconductor memory devices. However, these conventional ferroelectric materials suffer from various problems including poor Si-compatibility, environmental issues related to Pb, large phys. thickness, low resistance to hydrogen, and small bandgap.

In 2011, ferroelectricity in Si-doped HfO₂ thin films was reported for the first time. Various dopants, such as Si, Zr, Al, Y, Gd, Sr, and La can induce ferroelectricity or anti-ferroelectricity in thin HfO₂ films. They have large remanent polarization of up to 45 μC cm⁻², and their coercive field (≈1-2 MV cm⁻¹) is larger than conventional ferroelectric films by approximately one order of magnitude. Also, they can be extremely thin (<10 nm) and have a large bandgap (>5 eV). These differences are believed to overcome the barriers of conventional ferroelectrics in memory applications, including ferroelectric field-effect-transistors and three-dimensional capacitors. Also, the coupling of elec. and thermal properties of the antiferroelectric thin films are expected to be useful for various applications, including energy harvesting/storage, solid-state-cooling, and IR sensors.

There is a need in this art for precursors and methods for depositing silicon doped hafnium oxide containing films which can be thermally annealed to orthorhombic phase as ferroelectric materials used to fabricating future memory devices.

### SUMMARY OF THE INVENTION

The present invention solves problems associated with conventional precursors and processes by providing a formulation or composition (formulation and composition are exchangeable) comprising both organoaminohafnium and organoaminosilane precursor compounds having same organoamino ligands that allows anchoring both silicon-containing fragments and hafnium-containing fragments simultaneously onto a given surface having hydroxyl groups to deposit silicon doped hafnium oxide having a silicon doping level ranging from about 2 to about 6 mol. %, preferably about 3.00 to about 5.00 mol. %.

In one aspect, the present invention is a composition for depositing a silicon doped hafnium oxide film comprising:

(a) at least one organoaminosilane precursor compound having a formula of Si(NMe₂)₄ (tetrakis(dimethylamino)silane, also known as TDMAS) or Si(NEtMe)₄ (tetrakis(ethylmethylamino)silane, also known as TEMAS);
(b) at least one organoaminohafnium precursor compound having a formula of Hf(NMe₂)₄ (tetrakis(dimethylamino)hafnium, also known as TDMAH) or Hf(NEtMe)₄ (tetrakis(ethylmethylamino)hafnium, also known as TEMAH).

In another aspect, the present invention is a composition for depositing a silicon doped hafnium oxide film comprising:

an organoaminosilane precursor compound selected from the group consisting of tetrakis(dimethylamino)silane and tetrakis(ethylmethylamino)silane; and

an organoaminohafnium precursor compound selected the group consisting of tetrakis(dimethylamino)hafnium and tetrakis(ethylmethylamino)hafnium;

wherein the composition comprises at least one organoaminosilane precursor and at least one organoaminohafnium precursor having same organoamino ligands, and the composition includes less than 5 ppm of any halide impurities and less than 5 ppm of any metal impurities.

In another aspect, the present invention is a method to deposit a silicon doped hafnium oxide film as ferroelectric materials onto a substrate comprising the steps of:
a. providing a substrate in a reactor and heating up the substrate to a desired temperature;
b. introducing into the reactor a composition comprising: (a) at least one organoaminosilane precursor compound having a formula of Si(NMe₂)₄ or Si(NEtMe)₄ and (b) at least one organoaminohafnium precursor compound having a formula of Hf(NMe₂)₄ or Hf(NEtMe)₄;
c. purging the reactor with a purge gas;
d. introducing an oxygen-containing source into the reactor; and
e. purging the reactor with the purge gas;
wherein the steps b) through e) are repeated until a desired thickness of film is deposited; and the method is conducted at a temperature ranging from about 100° C. to 350° C.

The composition for depositing a silicon doped hafnium oxide film further comprises: (c) a solvent.

In one aspect, the present invention is also a vessel or container employing a composition or a composition with a solvent; wherein the composition comprises at least one of (a) at least one organoaminosilane precursor compound having a formula of Si(NMe₂)₄ or Si(NEtMe)₄ and (b) at least one organoaminohafnium precursor compound having a formula of Hf(NMe₂)₄ or Hf(NEtMe)₄.

Exemplary solvents can include, without limitation, ether, tertiary amine, alkyl hydrocarbon, aromatic hydrocarbon, siloxanes, tertiary aminoether, and combinations thereof.

The wt. % of organoaminosilane precursor compound in the formulation without solvent can vary from about 9.00 to about 11.00 wt. %; about 9.50 to about 10.50 wt. %, about 9.75% to about 10.25 wt. %, or about 9.90% to about 10.10 wt. %.

The wt. % of organoaminohafnium precursor compound in the formulation without solvent can vary from about 89.00 to about 91.00 wt. %; about 89.50 to about 90.50 wt. %, about 89.75 to about 90.25 wt. %, or about 89.90 to about 90.90 wt. %.

The formulations comprising the tetrakis(dimethylamino)silane and tetrakis(dimethylamino)hafnium with the wt. % ranges described above may be further diluted with a solvent such that the combined wt. % of organoaminosilane precursor plus organoaminohafnium precursor compounds in the formulation with the solvent can vary from about 0.01 to about 90.99 wt. %, about 10.00 to about 90.00 wt. %, or about 20.00 to about 80.00 wt. %, or about 30.00 to about 70.00 wt. %, or about 40.00 to about 60.00 wt. %. For example, a formulation comprising about 10 wt. % tetrakis(dimethylamino)silane and about 90 wt. % tetrakis(dimethylamino)hafnium may further be diluted with solvent such that the solvent concentration equals about 50 wt. %, the tetrakis(dimethylamino)silane concentration equals about 5 wt. %, and tetrakis(dimethylamino)hafnium concentration equals about 45 wt. %. In this example, the combined wt. % of the organoaminosilane precursor plus organoaminohafnium precursor compounds in the final composition equals about 50 wt. %.

In another aspect, the present invention is also a silicon doped hafnium oxide film having a silicon doping level ranging from about 2 to about 6 mol. %, preferably about 3.00 to about 5.00 mol. %, deposited using the disclosed compositions, methods, and systems.

In yet another aspect, the present invention is also a ferroelectric material containing the silicon doped hafnium oxide film having a silicon doping level ranging about 2 to about 6 mol. %, preferably about 3.00 to about 5.00 mol. %, deposited using the disclosed compositions, methods, and systems.

In some embodiments, the composition can be delivered via direct liquid injection into a reactor chamber for silicon-containing film.

The embodiments of the invention can be used alone or in combinations with each other.

### BRIEF DESCRIPTION OF THE DRAWINGS

FIG. 1 shows the amount of silicon doping in the Si:HfO₂ films deposited via ALD at different temperatures as a function of the concentration of tetrakis(dimethylamino)silane in the organoaminosilane/organoaminohafnium precursor formulation.

### DETAILED DESCRIPTION OF THE INVENTION

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

The present invention can be practiced using equipment known in the art. For example, the inventive method can use a reactor that is conventional in the semiconductor manufacturing art.

Atomic Layer Deposition (ALD) and Plasma Enhanced Atomic Layer Deposition (PEALD) are currently processes used to deposit silicon doped hafnium oxide employing super cycle approaches, i.e. many cycles of hafnium oxide followed by one or a few cycles of silicon oxide to control the amount of silicon dopant to provide ferroelectric material upon annealing the resulting nanolaminates to crystallize into orthorhombic phase.

In both ALD and PEALD processes, the precursors and reactive gas (such as oxygen, oxygen plasma, ozone, or water) are separately pulsed in certain number of cycles to form a multiple layers of hafnium oxide and monolayer of silicon oxide at each super cycle. However, the silicon dopants may not homogenously distribute into the crystal lattice, which may be detrimental in the performance of ferroelectric materials in semiconductor applications. To remedy this, one possible solution is to co-deposit both silicon oxide and hafnium oxide at each ALD or PEALD cycle, allowing better inter-mixing of silicon and hafnium atoms as well as creating Si—O—Hf or Hf—O—Si linkages, followed by thermal annealing to crystallize into proper orthorhombic phase suitable as ferroelectric material.

It is well known that hafnium oxide exists in three different crystal phases, monoclinic, tetragonal, and orthorhombic. Both monoclinic and tetragonal phases have been considered as high dielectric constant materials in the semi-conductor industrials. The crystallization in thin films tends to proceed by nucleation in a tetragonal phase and a martensitic transformation to the monoclinic phase during crystal growth. This phase transformation involves volume expansion and shearing of the unit cell. The admixture of sufficient SiO₂ (between 5 and 10 mol. %) has been found to stabilize the tetragonal phase in HfO₂. In addition, it was reported that also the presence of a top electrode during crystallization of HfO₂ thin films leads to a reduction of the monoclinic phase fraction and a significant increase in the dielectric constant. When silicon doping level is in the range of 2.00 to 6.00 mol. %, the formation of the monoclinic phase is inhibited if crystallization occurs under mechanical encapsulation and an orthorhombic phase is obtained. This phase shows a distinct piezoelectical response, while polarization measurements exhibit a remanent polarization above 10 μC/cm² at a coercive field of 1 MV/cm, suggesting that this phase is ferroelectric.

The composition disclosed in this invention allows not only better homogenous silicon doping into hafnium oxide, but also provides the optimal levels of silicon doping that are ideal for forming orthorhombic crystalline HfO₂ thin films upon annealing. Therefore, the composition disclosed herein may provide an advantage in one or more aspects with respect to either cost or convenience of precursor synthesis, physical properties of the precursor including thermal stability, melting point, compatibility, reactivity or volatility, the process of depositing a silicon doped hafnium oxide, cost or convenience of precursor delivery, ability to control the level of silicon doping, reproducibility and uniformity of silicon doping, or importantly the properties of the deposited silicon doped hafnium oxide film suitable as ferroelectric material.

Without wishing to be bound by any theory or explanation, it is believed that the effectiveness of the inventive formulation can allow proper doping of silicon atoms into hafnium oxide via tuning the weight percentage of organoaminosilane precursor, in particular, the organoaminosilane precursor has the same organoamino group as the organoaminohafnium precursor allowing both precursors to be chemically compatible with each other, i.e. no compositional change during storage or use but have different reactivity towards hydroxyl groups. It is also believed that the silicon doping levels in the silicon doped hafnium oxide material can be tuned by varying the deposition temperature based on the varying reactivity of the organoaminosilane and organoaminohafnium components.

The weight % or wt. % is to the total weight of the formulation or composition

In preferred embodiments, the composition comprises tetrakis(dimethyamino)silane, and tetrakis(dimethylamino)hafnium, wherein the weight percent (wt. %) ratio of tetrakis(dimethylamino)hafnium to tetrakis(dimethylamino)silane ranges from about 7 to 13 (equivalent to 7:1 to 13:1), 8 to 12 (or 8:1 to 12:1), or 9 to 11 (or 9:1 to 11:1). For example, a formulation that comprises 90 grams tetrakis(dimethylamino)hafnium and 10 grams tetrakis(dimethylamino)silane would have a TDMAH to TDMAS weight percent ratio of 9 (or 9:1). Similarly, a formulation that comprises 45 grams tetrakis(dimethylamino)hafnium, 5 grams tetrakis(dimethylamino)silane, and 50 grams solvent would also have a TDMAH to TDMAS weight percent ratio of 9 (or 9:1).

In a preferred embodiment, the composition comprises 9.89 wt. % tetrakis(dimethylamino)silane and 90.11 wt. % tetrakis(dimethylamino)hafnium.

In another preferred embodiment, the composition comprises about 10 wt. % (±1 wt. %) tetrakis(dimethylamino)silane, and about 90 wt. % (±1 wt. %) tetrakis(dimethylamino)hafnium.

In yet another preferred embodiment, the composition comprises tetrakis(dimethyamino)silane, tetrakis(dimethylamino)hafnium, and a solvent, wherein the weight percent (wt. %) ratio of tetrakis(dimethylamino)hafnium to tetrakis(dimethylamino)silane is 9.00 (±1.1).

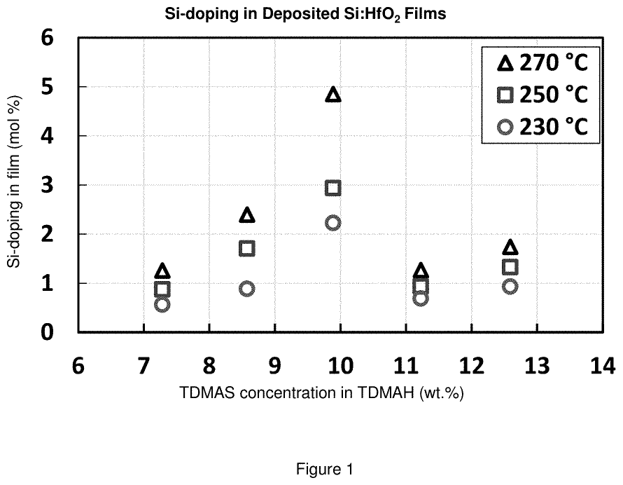

The composition disclosed in this invention has a unique ability to deposit a silicon doped hafnium oxide film having silicon doping levels ranging from about 2 to about 6 mol. %, preferably about 3.00 to about 5.00 mol. % which have been proven as ferroelectric materials (see FIG. 1), whereas similar compositions containing either slightly lower or higher concentrations of tetrakis(dimethylamino)silane in tetrakis(dimethylamino)hafnium, or that contain slightly lower or higher weight percent ratios (wt./wt.) of tetrakis(dimethylamino)hafnium to tetrakis(dimethylamino)silane, cannot be used under the same deposition conditions to achieve these preferable silicon doping levels.

Without wishing to be bound by any theory or explanation, it is believed that there is a range of tetrakis(dimethylamino)silane and tetrakis(dimethylamino)hafnium concentrations within a given formulation composition, which allows for the proper ratio of silicon atoms to hafnium atoms to be anchored during the precursor pulse step of each ALD cycle. When the concentrations of tetrakis(dimethylamino)silane and tetrakis(dimethylamino)hafnium or the ratios between tetrakis(dimethylamino)silane and tetrakis(dimethylamino)hafnium in the composition fall just outside the ranges disclosed in this invention, not enough silicon atoms can be anchored to the surface during the precursor pulse step, and thus the silicon doping levels in the resulting film are lower than optimal for the purpose of generated high amounts of orthorhombic phase crystalline HfO₂ in the manufacturing of a ferroelectric device. It is believed that a similar narrow range of preferred concentrations applies to compositions comprising tetrakis(ethylmethylamino)silane and tetrakis(ethylmethylamino)hafnium.

In one aspect, the composition for depositing a silicon doped hafnium oxide film comprises at least one of (a) at least one organoaminosilane precursor compound having a formula of Si(NMe₂)₄ or Si(NEtMe)₄ and (b) at least one organoaminohafnium precursor compound having a formula of Hf(NMe₂)₄ or Hf(NEtMe)₄.

In yet another aspect, there is provided a method to deposit a silicon doped hafnium oxide film using atomic layer deposition onto a substrate comprising the steps of:
a) providing the substrate in a reactor;
b) introducing into the reactor a composition comprising: (a) at least one organoaminosilane precursor compound having a formula of Si(NMe₂)₄ or Si(NEtMe)₄ and (b) at least one organoaminohafnium precursor compound having a formula of Hf(NMe₂)₄ or Hf(NEtMe)₄;
c) purging the reactor with a purge gas;
d) introducing an oxygen-containing source into the reactor; and
e) purging the reactor with the purge gas;
wherein the steps b) through e) are repeated until a desired thickness of film is deposited; and the method is conducted at a temperature ranging from about 100° C. to 350° C. In some embodiments, the oxygen-containing source in step d) is water because other oxygen-containing source such as ozone, oxygen plasma can potentially oxidize the substrate materials such as silicon or metal nitride (i.e. titanium nitride).

In yet another aspect, there is provided a system to deposit a silicon doped hafnium oxide film using atomic layer deposition onto a substrate comprising: the substrate in a reactor;

a composition comprising:
(a) at least one organoaminosilane precursor compound having a formula of Si(NMe₂)₄ or Si(NEtMe)₄ and
(b) at least one organoaminohafnium precursor compound having a formula of Hf(NMe₂)₄ or Hf(NEtMe)₄; and the system is at a temperature ranging from 100° C. to 350° C.

In another aspect, the composition for depositing a silicon doped hafnium oxide film further comprises: (c) a solvent.

In preferred embodiments, the ligands on the at least one organoaminosilane and the at least one organoaminohafnium precursor compounds in the composition are the same as to avoid generation of heteroleptic species due to ligand exchange.

In one aspect, the present invention is also a vessel or container employing a compound or a compound with a solvent; where the compound comprises at least one precursor compound is selected from the group consisting of (a) at least one organoaminosilane precursor compound having a formula of Si(NMe₂)₄; and (b) at least one organoaminohafnium precursor compound having a formula of Hf(NMe₂)₄.

In another aspect, the present invention is also a vessel or container employing a compound or a compound with a solvent; where the compound comprises at least one precursor compound is selected from the group consisting of (a) at least one organoaminosilane precursor compound having a formula of Si(NEtMe)₄; and (b) at least one organoaminohafnium precursor compound having a formula of Hf(NEtMe)₄.

Examples of suitable hafnium organoaminohafnium precursors having the formula LₓHf(NR¹R²)₄-ₓ that may be used with the method disclosed herein include, but are not limited to tetrakis(dimethylamino)hafnium (TDMAH), tetrakis(diethylamino)hafnium (TDEAH), tetrakis(ethylmethylamino)hafnium (TEMAH), tetrakis(pyrrolidino)hafnium, cyclopentadienyltris(dimethylamino)hafnium (CpHf(NMe₂)₃), methylcyclopentadienyltris(dimethylamino)hafnium (MeCpHf(NMe₂)₃), ethylcyclopentadienyltris(dimethylamino)hafnium (EtCpHf(NMe₂)₃), cyclopentadienyltris(ethylmethylamino)hafnium (CpHf(NMeEt)₃), methylcyclopentadienyltris(ethylmethylamino)hafnium (MeCpHf(NMeEt)₃), ethylcyclopentadienyltris(ethylmethylamino)hafnium (EtCpHf(NMeEt)₃), cyclopentadienyltris(diethylamino)hafnium (CpHf(NEt₂)₃), methylcyclopentadienyltris(diethylamino)hafnium (MeCpHf(NEt₂)₃), ethylcyclopentadienyltris(diethylamino)hafnium (EtCpHf(NEt₂)₃), bis(cyclopentadienyl)bis(dimethylamino)hafnium (Cp₂Hf(NMe₂)₂), bis(methylcyclopentadienyl)bis(dimethylamino)hafnium ((MeCp)₂Hf(NMe₂)₂), bis(ethylcyclopentadienyl)bis(dimethylamino)hafnium ((EtCp)₂Hf(NMe₂)₂), bis(cyclopentadienyl)bis(ethylmethylamino)hafnium (Cp₂Hf(NMeEt)₂), bis(methylcyclopentadienyl)bis(ethylmethylamino)hafnium ((MeCp)₂Hf(NMeEt)₂), bis(ethylcyclopentadienyl)bis(diethylamino)hafnium ((EtCp)₂Hf(NMeEt)₂), bis(cyclopentadienyl)bis(diethylamino)hafnium ((Cp₂Hf(NEt₂)₂), bis(methylcyclopentadienyl)bis(diethylamino)hafnium ((MeCp)2Hf(NEt₂)₃), bis(ethylcyclopentadienyl)bis(diethylamino)hafnium ((EtCp)₂Hf(NEt₂)₂), (N-methyl-2,4-cyclopentadiene-1-ethanamino]bis(dimethylamino)hafnium, (N-ethyl-2,4-cyclopentadiene-1-ethanamino]bis(dimethylamino)hafnium, (N-methyl-2,4-cyclopentadiene-1-ethanamino]bis(diethylamino)hafnium, (N-ethyl-2,4-cyclopentadiene-1-ethanamino]bis(diethylamino)hafnium, (N-methyl-2,4-cyclopentadiene-1-ethanamino]bis(ethylmethylamino)hafnium, (N-ethyl-2,4-cyclopentadiene-1-ethanamino]bis(ethylmethylamino)hafnium, and combinations thereof.

In some embodiments, an oxygen-containing source employed in the method is a source selected from the group consisting of an oxygen plasma, ozone, hydrogen peroxide, a water vapor, water vapor plasma, nitrogen oxide (e.g., N₂O, NO, NO₂) plasma with or without inert gas, a carbon oxide (e.g., CO₂, CO) plasma and combinations thereof. In certain embodiments, the oxygen source further comprises an inert gas. In these embodiments, the inert gas is selected from the group consisting of argon, helium, nitrogen, hydrogen, and combinations thereof. In an alternative embodiment, the oxygen source does not comprise an inert gas.

In certain embodiments of the composition described herein, exemplary solvents can include, without limitation, ether, tertiary amine, alkyl hydrocarbon, aromatic hydrocarbon, siloxanes, tertiary aminoether, and combinations thereof.

The wt. % of tetrakis(dimethylamino)silane in the formulation without solvent can vary from 9.00 to 11.00 wt. %; 9.50 to 10.50 wt. %, 9.75% to 10.25 wt. %, or 9.90% to 10.10 wt. %.

The wt. % of tetrakis(dimethylamino)hafnium in the formulation without solvent can vary from 89.00 to 91.00 wt. %; 89.50 to 90.50 wt. %, 89.75 to 90.25 wt. %, or 89.90 to 90.10 wt. %.

The wt. % of tetrakis(ethylmethyl)silane in the formulation without solvent can vary from 9.50 to 11.50 wt. %; 9.50 to 12.00 wt. %, 10.00% to 11.00 wt. %, or 9.90% to 11.10 wt. %.

The wt. % of tetrakis(ethylmethyl)hafnium in the formulation without solvent can vary from 88.50 to 90.50 wt. %; 88.00 to 90.50 wt. %, 89.00 to 90.00 wt. %, or 88.90 to 90.10 wt. %.

The formulations comprising the tetrakis(dimethylamino)silane and tetrakis(dimethylamino)hafnium with the wt. % ranges described above may be further diluted with a solvent such that the combined wt. % of organoaminosilane precursor plus organoaminohafnium precursor compounds in the formulation with the solvent can vary from about 0.01 to about 99.99 wt. %, about 10.00 to about 90.00 wt. %, about 20.00 to about 80.00 wt. %, about 30.00 to about 70.00 wt. %, or about 40.00 to about 60.00 wt. %.

The concentration of the solvent in these formulations can vary from about 0.01 to about 99.99 wt. %, or about 10.00 to about 90.00 wt. %, or about 20.00 to about 80.00 wt. %, or about 30.00 to about 70.00 wt. %, or about 40.00 to about 60.00 wt. %.

In one embodiment, a formulation comprising 10 wt. % tetrakis(dimethylamino)silane and 90 wt. % tetrakis(dimethylamino)hafnium may further be diluted with solvent such that the final solvent concentration equals 50 wt. % the tetrakis(dimethylamino)silane concentration equals 5 wt. %, and tetrakis(dimethylamino)hafnium concentration equals 45 wt. %. In this example, the combined wt. % of the organoaminosilane precursor plus organoaminohafnium precursor compounds in the final composition equals 50 wt. %.

In another aspect, the present invention is also a silicon doped hafnium oxide film having a silicon doping level ranging from about 2.00 to about 5.00 mol. %, deposited using the disclosed compositions, methods, and systems. In some embodiments, the ferroelectric material comprises hafnium, silicon, and oxygen; In other embodiments, the ferroelectric material comprises hafnium, silicon, oxygen, and carbon. The content of carbon can be less than about 1.00 at. % or less, about 0.50 at. % or less, about 0.10 at. % or less, about 0.01 at. % or less; Yet in another embodiment, the ferroelectric material comprises hafnium, silicon, oxygen, carbon, and nitrogen. The content of carbon can be less than about 1.00 at. % or less, about 0.50 at. % or less, about 0.10 at. % or less, about 0.01 at. % or less and the content of nitrogen can be less than about 1.00 at. % or less, about 0.50 at. % or less, about 0.10 at. % or less, about 0.01 at. % or less.

In yet another aspect, the present invention is also a ferroelectric material containing the silicon doped hafnium oxide film having a silicon doping level ranging about 2 to about 6 mol. %, preferably about 3.00 to about 5.00 mol. % deposited using the disclosed compositions, methods and systems.

In some embodiments, the composition can be delivered via direct liquid injection into a reactor chamber for silicon-containing film.

The embodiments of the invention can be used alone or in combinations with each other.

Throughout the description, “silicon doping level” is defined as (Si at. %)/(Si at. %+Hf at. %), that is, the atomic Si percentage divided by the sum of atomic Si and atomic Hf percentages as measured by XPS (X-ray Photoelectron Spectroscopy) or SIMS (Secondary Ion Mass Spectrometry). For example, a 3 mol. % silicon doping level in a silicon doped hafnium oxide film means that 3 out of 100 Hf atoms in a hafnium oxide material have been substituted by silicon atoms, such that the Si:Hf molar ratio in the silicon doped hafnium oxide film is 3:97 (3/(3+97)=3.00 mol. % silicon doping level). In this example, a 3.00 mol. % silicon doping level in HfO₂ equates to an overall Si content of 1.00 at. % as measured by XPS or SIMS. Thus, 0.50 to 8.00 mol. % silicon doping level corresponds to 0.17 at. % to 2.67 at. % as measured by XPS or SIMS, 2 to 6 mol. % silicon doping level corresponds to 0.67 at. % to 2.00 at. % as measured by XPS or SIMS. The silicon doping level can have up to two decimal points, for example, 2 out of 99 Hf atoms in a hafnium oxide material have been substituted by silicon atoms, the silicon doping level is defined as 2.02 mol. %.

Throughout the description, “wt. %” is defined as weight of organoaminosilane precursors /(weight of organoaminosilane precursors+weight of organoaminohafnium precursors) or weight of organoaminosilane precursors/(weight of organoaminosilane precursors+weight of organoaminohafnium precursors+weight of solvent). The wt. % can have up to two decimal points, that is the range of 0.10 to 5.00 wt. % covers any weight percentage from 0.10 to 5.00 wt. % with two decimal points. For example, a formulation comprising 9.9 grams tetrakis(dimethylamino)silane and 90.1 grams tetrakis(dimethylamino)hafnium, having a total mass of 100.0 grams, can be referred to as “9.9 wt. % tetrakis(dimethylamino)silane in tetrakis(dimethylamino)hafnium” or “9.9 wt. % TDMAS in TDMAH”.

Throughout the description, the word “about” is used before a value for percentage or temperature to indicate the value can have up to 10% error bar, for example about 10.00 wt. % covers the weight percentage from 9.00 wt. % to 11.00 wt. %, unless otherwise specified. Likewise, about 2 wt. %, covers any percentage from 1.80 to 2.20 wt. %.

In the formula above and throughout the description, the term “alkyl” denotes a linear or branched functional group having from 1 to 10 carbon atoms. Exemplary linear alkyl groups include, but are not limited to, methyl, ethyl, propyl, butyl, pentyl, and hexyl groups. Exemplary branched alkyl groups include, but are not limited to, iso-propyl, iso-butyl, sec-butyl, tert-butyl, iso-pentyl, tert-pentyl, iso-hexyl, and neo-hexyl. In certain embodiments, the alkyl group may have one or more functional groups attached thereto such as, but not limited to, an alkoxy group, a dialkylamino group or combinations thereof, attached thereto. In other embodiments, the alkyl group does not have one or more functional groups attached thereto. The alkyl group may be saturated or, alternatively, unsaturated.

In certain embodiments, substituents R¹ and R² in the formula can be linked together to form a ring structure. As the skilled person will understand, where R¹ and R² are linked together to form a ring. In these embodiments, the ring structure can be unsaturated such as, for example, a cyclic alkyl ring, or saturated, for example, an aryl ring. Further, in these embodiments, the ring structure can also be substituted or unsubstituted with one or more atoms or groups. Exemplary cyclic ring groups include, but not limited to, pyrrolidino, piperidino, and 2,6-dimethylpiperidino groups. In other embodiments, however, substituent R¹ and R² are not linked to form a ring structure.

Throughout the description, the term “organoamino group” refers to R¹R²N- wherein R¹ and R² are independently selected from linear or branched C₁ to C₆ alkyl. In some cases, R¹ and R² are linked to form a cyclic ring structure, in other cases R¹ and R² are not linked to form a cyclic ring structure. Exemplary organoamino groups wherein R¹ and R² are not linked to form a cyclic ring includes, but not limited to, dimethylamino, ethylmethylamino, diethylamino. Exemplary organoamino groups wherein R¹ and R² are linked to form a cyclic ring includes, but not limited to, pyrrolidino wherein R¹=propyl and R²=Me, piperidino wherein R¹=propyl and R²=Et, 2,6-dimethylpiperidino wherein R¹=iso-propyl and R²=sec-butyl, and 2,5-dimethylpyrrolidinodilane wherein R¹=R²=iso-propyl.

Throughout the description, the term “aromatic hydrocarbon” refers to a C₆ to C₂₀ aromatic hydrocarbon. Exemplary aromatic hydrocarbon n includes, but not limited to, toluene, mesitylene.

Throughout the description, the term “alkyl substituted cyclopentadienyl” refers to a linear or branched C₁ to C₆ hydrocarbon bonded to cyclopentadienyl. Exemplary alkyl substituted cyclopentadienyl groups includes, but is not limited to, methylcyclopentadienyl, ethylcyclopentadienyl, iso-propylcyclopentadienyl, sec-butylcyclopentadienyl, and tert-butylcyclopentadienyl. In some particular embodiments, the alkyl group has nitrogen atom which can coordinated to hafnium. Exemplary such as alkyls include, but not limited to N-methyl-2,4-cyclopentadiene-1-ethanamine, N-ethyl-2,4-Cyclopentadiene-1-ethanamine. Organoaminohafnium having such alkyl substituted cyclopentadienyl groups include, but not limited to, (N-methyl-2,4-cyclopentadiene-1-ethanamino]bis(dimethylamino)hafnium, (N-ethyl-2,4-cyclopentadiene-1-ethanamino]bis(dimethylamino)hafnium, (N-methyl-2,4-cyclopentadiene-1-ethanamino]bis(diethylamino)hafnium, (N-ethyl-2,4-cyclopentadiene-1-ethanamino]bis(diethylamino)hafnium, (N-methyl-2,4-cyclopentadiene-1-ethanamino]bis(ethylmethylamino)hafnium, (N-ethyl-2,4-cyclopentadiene-1-ethanamino]bis(ethylmethylamino)hafnium.

Throughout the description, the terms “composition” or “formulation” are interchangeable. In one embodiment, the formulation is selected from the group consisting of:
(a) at least one organoaminosilane precursor compound having a formula of Si(NMe₂)₄; and (b) at least one organoaminohafnium precursor compound having a formula of Hf(NMe₂)₄.
   Optionally, the “composition” or “formulation” further comprises a solvent.

The composition or formulation comprising tetrakis(dimethylamino)silane and tetrakis(dimethylamino)hafnium according to the present invention is preferably substantially free of halide ions. As used herein, the term “substantially free” as it relates to halide ions (or halides) such as, for example, chlorides (i.e. chloride-containing species such as HCl or silicon compounds having at least one Si-Cl bond such as (Me₂N)₃SiCl) and fluorides, bromides, and iodides, means less than 5 ppm (by weight) measured by ion chromatography (IC), preferably less than 3 ppm measured by ion chromatography (IC), and more preferably less than 1 ppm measured by ion chromatography (IC), and most preferably 0 ppm measured by ion chromatography (IC). It is believed that significant levels of chloride in the formulation can be detrimental to the device performance. The formulation is also preferably substantially free of metal ions or metal impurities such as, Li⁺, Al³⁺, Fe²⁺, Fe²⁺, Fe³⁺, Ni²⁺, Cr³⁺, volatile metal complexes. As used herein, the term “substantially free” as it relates to Li, Al, Fe, Ni, Cr means less than 5 ppm (by weight), preferably less than 3 ppm, and more preferably less than 1 ppm, and most preferably 0.1 ppm as measured by ICP-MS. As used herein, the term “free of” as it relates to Li, Al, Fe, Ni, Cr, noble metal such as Ru or Pt (ruthenium (Ru) or platinum (Pt) from the catalysts used in the synthesis), means less than 1 ppm (by weight) as measured by ICP-MS, preferably less than 0.1 ppm as measured by ICP-MS, and more preferably less than 0.01 ppm as measured by ICP-MS, and most preferably 5 ppb as measured by ICP-MS.

In one or more embodiments described above, the oxygen-containing source is a source selected from the group consisting of an oxygen plasma, ozone, hydrogen peroxide, a water vapor, water vapor plasma, nitrogen oxide (e.g., N₂O, NO, NO₂) plasma with or without inert gas, a carbon oxide (e.g., CO₂, CO) plasma and combinations thereof.

In certain embodiments, the oxygen-containing source further comprises an inert gas. In these embodiments, the inert gas is selected from the group consisting of argon, helium, nitrogen, and combinations thereof.

In an alternative embodiment, the oxygen-containing source does not comprise an inert gas.

Throughout the description, the term “ALD or ALD-like” refers to a process including, but is not limited to, the following processes: a) each reactant including a silicon precursor and a reactive gas is introduced sequentially into a reactor such as a single wafer ALD reactor, semi-batch ALD reactor, or batch furnace ALD reactor; b) each reactant including the silicon precursor and the reactive gas is exposed to a substrate by moving or rotating the substrate to different sections of the reactor and each section is separated by inert gas curtain, i.e., spatial ALD reactor or roll to roll ALD reactor. A typical cycle of an ALD or ALD-like process comprises at least four steps as aforementioned.

In certain embodiments, silicon doped hafnium oxide films deposited using the methods described herein are formed in the presence of oxygen-containing source comprising ozone, hydrogen peroxide (H₂O₂), water (H₂O) (e.g., deionized water, purifier water, and/or distilled water), oxygen (O₂), oxygen plasma, NO, N₂O, NO₂, carbon monoxide (CO), carbon dioxide (CO₂) and combinations thereof.

The oxygen-containing source is passed through, for example, either an in situ or remote plasma generator to provide oxygen-containing plasma source comprising oxygen such as an oxygen plasma, a plasma comprising oxygen and argon, a plasma comprising oxygen and helium, an ozone plasma, a water plasma, a nitrous oxide plasma, or a carbon dioxide plasma.

In certain embodiments, the oxygen-containing source comprises an oxygen source gas that is introduced into the reactor at a flow rate ranging from about 1 to about 2000 standard cubic centimeter per minute (sccm) or from about 1 to about 1000 sccm.

The oxygen-containing source can be introduced for a time that ranges from about 0.1 to about 100 seconds.

In one particular embodiment, the oxygen-containing source comprises water having a temperature of 10° C. or greater.

In embodiments wherein the film is deposited by a PEALD or a plasma enhanced cyclic CVD process, the precursor pulse can have a pulse duration that is greater than 0.01 seconds (e.g., about 0.01 to about 0.1 seconds, about 0.1 to about 0.5 seconds, about 0.5 to about 10 seconds, about 0.5 to about 20 seconds, about 1 to about 100 seconds) depending on the ALD reactor's volume, and the oxygen-containing source can have a pulse duration that is less than 0.01 seconds (e.g., about 0.001 to about 0.01 seconds).

The deposition methods disclosed herein may involve one or more purge gases. The purge gas, which is used to purge away unconsumed reactants and/or reaction byproducts, is an inert gas that does not react with the precursors.

Exemplary purge gases include, but are not limited to, argon (Ar), nitrogen (N₂), helium (He), neon, hydrogen (H₂), and mixtures thereof. In certain embodiments, a purge gas such as Ar is supplied into the reactor at a flow rate ranging from about 10 to about 2000 sccm for about 0.1 to 1000 seconds, thereby purging the unreacted material and any byproduct that may remain in the reactor.

The respective step of supplying the precursors, oxygen source, and/or other precursors, source gases, and/or reagents may be performed by changing the time for supplying them to change the stoichiometric composition of the resulting dielectric film.

Energy is applied to at least one of the silicon precursors/formula, oxygen containing source, or combination thereof to induce reaction and to form the silicon doped hafnium oxide on the substrate and then to convert the resulting film into orthorhombic form suitable as ferroelectric material.

Such energy can be provided by, but not limited to, thermal, plasma, pulsed plasma, helicon plasma, high density plasma, inductively coupled plasma, X-ray, e-beam, photon, remote plasma methods, and combinations thereof. Thermal annealing can be done at temperatures up to 1000° C.

In certain embodiments, a secondary RF frequency source can be used to modify the plasma characteristics at the substrate surface.

In embodiments wherein the deposition involves plasma, the plasma-generated process may comprise a direct plasma-generated process in which plasma is directly generated in the reactor, or alternatively, a remote plasma-generated process in which plasma is generated outside of the reactor and supplied into the reactor.

The at least one formulation compound may be delivered to the reaction chamber such as a plasma enhanced cyclic CVD or PEALD reactor or a batch furnace type reactor in a variety of ways.

In one embodiment, a liquid delivery system may be utilized.

In another embodiment, a vessel or container employing a composition comprising at least one organoaminosilane precursor compound, and/or at least one organoaminohafnium precursor compound, and/or solvent for depositing a silicon doped hafnium oxide is described herein.

In one particular embodiment, the vessel or container (vessel and container are exchangeable) comprises at least one pressurizable vessel (preferably of stainless steel) fitted with the proper valves and fittings to allow the delivery of one or more precursors to the reactor for deposition process, such as a CVD or an ALD process. In this or other embodiments, the composition comprising at least one organoaminosilane precursor compound and at least one organoaminohafnium precursor compound is provided in a pressurizable vessel comprised of stainless steel and the purity of the precursor is 98% by weight or greater or 99.5% or greater which is suitable for the majority of semiconductor applications, as well as at least one inert gas selected from the group consisting of argon (Ar), nitrogen (N₂), helium (He), neon, and combinations thereof.

In certain embodiments, such vessels can also have means for mixing the precursors with one or more additional precursor if desired. In these or other embodiments, the contents of the vessel(s) can be premixed with an additional precursor.

In certain embodiments, the gas lines connecting from the composition canisters to the reaction chamber are heated to one or more temperatures depending upon the process requirements and the container of the composition described herein is kept at one or more temperatures for bubbling. In other embodiments, a composition comprising the at least one organoaminosilane precursor compound and at least one organoaminohafnium precursor compound described herein is injected into a vaporizer kept at one or more temperatures for direct liquid injection.

In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor.

In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

As previously mentioned, the purity level of the at least one organoaminosilane or organoaminohafnium precursor compound in the formulation is sufficiently high enough to be acceptable for reliable semiconductor manufacturing. In certain embodiments, the at least one organoaminosilane precursor compound described herein comprises less than 2% by weight, or less than 1% by weight, or less than 0.5% by weight of one or more of the following impurities: free amines, free halides or halogen ions, and higher molecular weight species. Higher purity levels of the silicon precursor described herein can be obtained through one or more of the following processes: purification, adsorption, and/or distillation.

In one embodiment of the method described herein, a plasma enhanced cyclic deposition process such as PEALD-like or PEALD may be used wherein the deposition is conducted using the at least one organoaminosilane precursor compound and an oxygen containing source. The PEALD-like process is defined as a plasma enhanced cyclic CVD process but still provides high conformal hafnium-, silicon-, and oxygen-containing films.

In certain embodiments, the gas lines connecting from the precursor canisters to the reaction chamber are heated to one or more temperatures depending upon the process requirements and the container of the at least one formulation comprising at least one organoaminosilane and/or the at least one organoaminohafnium precursor compound is kept at room temperature for direct liquid injection (DLI) as vapors. In other embodiments, a formulation comprising at least one organoaminosilane and/or the at least one organoaminohafnium precursor compound is injected into a vaporizer kept at one or more temperatures ranging from room temperature to about 60° C. for direct liquid injection.

A flow of argon and/or other gas may be employed as a carrier gas to help deliver the vapor of the at least one formulation comprising at least one organoaminosilane and/or at least one organoaminohafnium precursor compound to the reaction chamber during the precursor pulsing.

In certain embodiments, the reaction chamber process pressure is about 50 mTorr to 10 Torr. In other embodiments, the reaction chamber process pressure can be up to 760 Torr (e.g., about 50 mTorr to about 100 Torr).

In a typical PEALD or a PEALD-like process such as a PECCVD process, the substrate such as a silicon oxide substrate is heated on a heater stage in a reaction chamber that is exposed to the organoaminosilane and/or organoaminohafnium precursor compound initially to allow the complex(es) to chemically adsorb onto the surface of the substrate.

A purge gas such as argon purges away unabsorbed excess complex from the process chamber. After sufficient purging, an oxygen source may be introduced into reaction chamber to react with the absorbed surface followed by another gas purge to remove reaction by-products from the chamber. The process cycle can be repeated to achieve the desired film thickness. In some cases, pumping can replace a purge with inert gas or both can be employed to remove unreacted silicon precursors.

In this or other embodiments, it is understood that the steps of the methods described herein may be performed in a variety of orders, may be performed sequentially, may be performed concurrently (e.g., during at least a portion of another step), and any combination thereof. The respective step of supplying the precursors and the oxygen source gases, for example, may be performed by varying the duration of the time for supplying them to change the stoichiometric composition of the resulting dielectric film. Also, purge times after precursor or oxidant steps can be minimized to <0.1 s so that throughput is improved.

Various commercial ALD reactors such as single wafer, semi-batch, batch furnace or roll to roll reactor can be employed for depositing the silicon doped hafnium oxide.

Process temperature for the method described herein use one or more of the following temperatures as endpoints: 100° C., 125° C., 150° C., 175° C., 200° C., 225° C., 230° C., 235° C., 240° C., 245° C., 250° C., 255° C., 260° C., 265° C., 270° C., 275° C., 280° C., 285° C., 290° C., 295° C., 300° C., 325° C., 350° C.; preferably 200° C., 225° C., 250° C., 275° C., 300° C.

Exemplary temperature ranges include, but are not limited to the following: from about 200° C. to about 300° C.; or from about 100° C. to about 300° C.; or from about 150° C. to about 290° C.; or from about 125° C. to about 280° C., or from about 250° C. to about 300° C.

Or, exemplary temperature ranges include, but are not limited to the following: from about from about 100° C. to 350° C.; about 125° C. to 325° C., about 150° C. to 325° C., about 200° C. to 300° C.; about 220° C. to 300° C., or about 230° C. to 300° C.

Without intending to be bound by a particular theory, it is believed that deposition temperatures greater than 300° C., and more so greater than 350° C., may allow premature crystallization of the deposited Si:HfO₂ film during deposition, which is not preferred when manufacturing a ferroelectric device because it could reduce the presence of the preferred orthorhombic crystalline phase in the final film.

In a still further embodiment of the method described herein, the film or the as-deposited film deposited from ALD, ALD-like, PEALD, or PEALD-like is subjected to a treatment step (post deposition) to convert into crystal phase suitable for ferroelectric materials. The treatment step can be conducted during at least a portion of the deposition step, after the deposition step, and combinations thereof.

Exemplary post-treatment steps include, without limitation, treatment via high temperature thermal annealing such as rapid thermal annealing (RTA), spike annealing, or flash lamp annealing (FLA) at temperatures from 500 to 1000° C., or from 600 to 900° C., or from 600 to 800° C. to convert the as-deposited silicon doped hafnium oxide into orthorhombic phase; The thermal treatment can be performed via one step or multi-steps. Other post-treatment such as plasma treatment; ultraviolet (UV) light treatment; laser; electron beam treatment and combinations can also be employed thereof to affect one or more properties of the film.

In one particular embodiment, during the deposition process, as-deposited films are intermittently treated. These intermittent or mid-deposition treatments can be performed, for example, after each ALD cycle, after every certain number of ALD cycles, such as, without limitation, one (1) ALD cycle, two (2) ALD cycles, five (5) ALD cycles, or after every ten (10) or more ALD cycles. The thickness of the resulting silicon doped hafnium oxide ranges from 10 Å to 500 Å, or 30 Å to 400 Å, or 40 Å to 200 Å, or 40 Å to 100 Å, or 40 Å to 80 Å.

As mentioned previously, the method described herein may be used to deposit a silicon doped hafnium oxide film on at least a portion of a substrate. Examples of suitable substrates include but are not limited to, silicon, SiO₂, titanium nitride, tungsten nitride, tantalum nitride, vanadium nitride, metals such as copper, titanium, tungsten, cobalt, ruthenium, platinum palladium, aluminum and any other suitable electrode materials in the fabrication of ferroelectric devices.

The films are compatible with a variety of subsequent processing steps such as, for example, chemical mechanical planarization (CMP) and anisotropic etching processes.

The deposited films have applications, which include, but are not limited to, computer chips, optical devices, magnetic information storages, coatings on a supporting material or substrate, microelectromechanical systems (MEMS), nanoelectromechanical systems, thin film transistor (TFT), light emitting diodes (LED), organic light emitting diodes (OLED), IGZO, and liquid crystal displays (LCD). Potential use of resulting solid silicon doped hafnium oxide include, but not limited to, shallow trench insulation, inter layer dielectric, passivation layer, an etch stop layer, part of a dual spacer, and sacrificial layer for patterning.

### EXAMPLES

In the following examples, unless stated otherwise, properties will be obtained from sample films that are deposited onto silicon wafer with resistivity of 5-20 Ω-cm as substrate or PVD TiN wafer having TiN 100-500 Å/bare Si sub-structure as substrate. All film depositions are performed using the CN-1 reactor has showerhead design with 13.56 MHz direct plasma. The dip tube side of the canister, containing the liquid mixture formulation of Hf and Si precursors, is connected to a direct liquid injection (DLI) system/apparatus, where the formulation is vaporized through an injector, allowing the ratio of vapors to be same as that in the liquid mixture and Ar gas is added to deliver the vapor effectively into the ALD reactor chamber, and pressurized N₂ (˜15 psig) is connected to the other side of the canister to push the liquid.

In typical process conditions, unless stated otherwise, the chamber pressure is fixed at a pressure ranging from about 1 to about 5 Torr. Additional inert gas is used to maintain chamber pressure.

When O₃ is used as a reactant, an ozone generator is used to generate mixture of O₃ and O₂. O₂ input flow rate is 500 sccm and N₂ input flow rate as a catalyst is 5 sccm, and this will make a mixture of O₃ and O₂ with O₃ concentration of 280˜320 g/Nm³.

TABLE 1
Deposition Steps in ALD Silicon Doped Hafnium Oxide Films

Step

| | |
|---|---|
| a | Provide the substrate in a reactor and heat up the substrate to a |
| | desired temperature |
| b | Introduce vapors of the formulation to the reactor; additional inert |
| | gas is used to maintain chamber pressure to provide a chemisorbed |
| | layer |
| c | Purge unreacted formulation precursor from the reactor chamber |
| | with inert gas |
| d | Introduce an oxygen-containing source with or without activating |
| | plasma to react with the surface of the chemisorbed layer and |
| | create reactive sites |
| e | Purge reaction by-products out |

The formulation is delivered as vapors using direct liquid injection (DLI) system (Horiba STEC, Co., Ltd, Japan). Typical RF power used is 300 W over electrode area of 200 mm wafer. The film depositions comprise the steps listed in Table 1 for thermal ALD and plasma enhanced ALD. Steps b through e in Table 1 constitute one ALD or PEALD cycle and are repeated, unless otherwise specified, a total of, for example, 100 or 200 or 300 or 500 times to get the desired film thickness.

The reactive index (RI) and thickness for the deposited films are measured using an ellipsometer. Film non-uniformity is calculated using the standard equation: % non-uniformity=((max thickness−min thickness)/(2*average (avg) thickness)). Film structure and composition are analyzed using Fourier Transform Infrared (FTIR) spectroscopy, X-Ray Photoelectron Spectroscopy (XPS) and Secondary Ion Mass Spectrometry (SIMS). The density for the films is measured with X-ray Reflectometry (XRR).

### Example 1

ALD of silicon doped hafnium oxide using various wt. % of tetrakis(dimethylamino)silane (TDMAS) in formulations comprising tetrakis(dimethylamino)silane (TDMAS) and tetrakis(dimethylamino)hafnium (TDMAH) and ozone as oxygen-containing source.

The silicon wafer coated with a 100-200 Å thick film of PVD TiN was loaded into the CN-1 reactor equipped with showerhead design with 13.56 MHz direct plasma and heated to 230° C., 250° C., or 270° C. with chamber pressure of 1 torr. Formulations comprising tetrakis(dimethylamino)silane and tetrakis(dimethylamino)hafnium with various concentrations of tetrakis(dimethylamino)silane (4.8 wt. %, 6.0 wt. %, 7.3 wt. %, 8.6 wt. %, 9.9 wt. %, 11.2 wt. %, and 12.6 wt. %) were used as the precursors and were delivered as vapors into the reactor using DLI with a flow rate of 10 mg/min through an injector.

The ALD cycle was comprised of the process steps provided in Table 1 and used the following process parameters:
a. Provide a substrate in an ALD reactor and heat up the substrate to a desired temperature
b. Introduce vapors of the formulation precursor with Ar gas (250 sccm) to the reactor
   a. Total Argon flow: 1250 sccm
   b. Formulation precursor pulse: 1 to 5 seconds
c. Inert gas purge
   a. Argon flow: 1000 sccm
   b. Purge time: 2030 seconds
d. Introduce ozone
   a. Argon flow: 1000 sccm
   b. Ozone concentration: 280320 g/Nm³
   c. Ozone pulse: 5 to 20 seconds
e. Purge
   a. Argon flow: 1000 sccm
   b. Purge time: 2030 seconds

Steps b to e were repeated for a certain number of cycles to provide certain thickness of silicon doped hafnium oxide. The deposited film was then annealed at 600° C. for 30 seconds. The thickness of each film was measured by ellipsometry and the various silicon doping levels were measured by SIMS. The deposition results for each formulation are shown in Table 2 (230° C.), Table 3 (250° C.), and Table 4 (270° C.).

TABLE 2
Summary of deposition conditions, film thickness, and
SIMS measurements for depositions performed at 230° C.

| TDMAS | TDMAH | | | | Hf | O | Si | Si/(Si + Hf) |
|---|---|---|---|---|---|---|---|---|
| conc. | conc. | Cycles | Sub | THK, Å | (at. %) | (at. %) | (at. %) | (mol. %) |
| 7.3 wt. % | 92.7 wt. % | 85 | TiN | 110 | 35.35 | 64.46 | 0.20 | 0.57 |
| 8.6 wt. % | 91.4 wt. % | 85 | TiN | 109 | 34.70 | 65.00 | 0.31 | 0.89 |
| 9.9 wt. % | 90.1 wt. % | 85 | TiN | 111 | 34.26 | 64.94 | 0.78 | 2.23 |
| 11.2 wt. % | 88.8 wt. % | 85 | TiN | 112 | 35.90 | 63.90 | 0.25 | 0.69 |
| 12.6 wt. % | 87.4 wt. % | 85 | TiN | 111 | 40.40 | 59.20 | 0.38 | 0.93 |

TABLE 3
Summary of deposition conditions, film thickness, and
SIMS measurements for depositions performed at 250° C.

| TDMAS | TDMAH | | | | Hf | O | Si | Si/(Si + Hf) |
|---|---|---|---|---|---|---|---|---|
| conc. | conc. | Cycles | Sub | THK, Å | (at. %) | (at. %) | (at. %) | (mol. %) |
| 7.3 wt. % | 92.7 wt. % | 85 | TiN | 113 | 32.86 | 66.82 | 0.29 | 0.88 |
| 8.6 wt. % | 91.4 wt. % | 85 | TiN | 113 | 34.00 | 65.40 | 0.59 | 1.71 |
| 9.9 wt. % | 90.1 wt. % | 85 | TiN | 113 | 33.33 | 65.63 | 1.01 | 2.94 |
| 11.2 wt. % | 88.8 wt. % | 85 | TiN | 113 | 34.90 | 64.70 | 0.33 | 0.94 |
| 12.6 wt. % | 87.4 wt. % | 85 | TiN | 113 | 36.40 | 63.10 | 0.49 | 1.33 |

TABLE 4
Summary of deposition conditions, film thickness, and
SIMS measurements for depositions performed at 270° C.

| TDMAS | TDMAH | | | | Hf | O | Si | Si/(Si + Hf) |
|---|---|---|---|---|---|---|---|---|
| conc. | conc. | Cycles | Sub | THK, Å | (at. %) | (at. %) | (at. %) | (mol. %) |
| 7.3 wt. % | 92.7 wt. % | 81 | TiN | 110 | 31.40 | 68.17 | 0.4 | 1.26 |
| 8.6 wt. % | 91.4 wt. % | 81 | TiN | 112 | 33.80 | 65.30 | 0.83 | 2.40 |
| 9.9 wt. % | 90.1 wt. % | 82 | TiN | 107 | 30.71 | 67.67 | 1.57 | 4.86 |
| 11.2 wt. % | 88.8 wt. % | 81 | TiN | 112 | 33.40 | 66.20 | 0.44 | 1.30 |
| 12.6 wt. % | 87.4 wt. % | 81 | TiN | 113 | 35.00 | 64.40 | 0.62 | 1.74 |

The amount of silicon doping in the Si:HfO₂ films deposited via ALD at different temperatures as a function of the concentration of tetrakis(dimethylamino)silane in the organoaminosilane/organoaminohafnium precursor formulation was shown in FIG. 1.

As shown in FIG. 1, the formulation containing about 9.9 wt. tetrakis(dimethylamino)silane in tetrakis(dimethylamino)hafnium yielded unexpected higher silicon doping levels in the deposited Si:HfO₂ film than the formulations containing 1.3-2.6 wt. % less tetrakis(dimethylamino)silane or 1.3-2.7 wt. % more tetrakis(dimethylamino)silane. The Si doping levels achieved with the 9.9 wt. % tetrakis(dimethylamino)silane formulation at 230° C., 250° C., and 270° C. are all within 2 to 6 mol. % range of Si doping that is optimal for forming films as ferroelectric material.

The foregoing examples and description of the embodiments should be taken as illustrating, rather than as limiting the present invention as defined by the claims. As will be readily appreciated, numerous variations and combinations of the features set forth above can be utilized without departing from the present invention as set forth in the claims. Such variations are intended to be included within the scope of the following claims.

1. A composition for atomic layer deposition of a silicon doped hafnium oxide film comprising:
at least one organoaminosilane precursor selected from the group consisting of tetrakis(dimethylamino)silane, and tetrakis(ethylmethylamino)silane; and
at least one organoaminohafnium precursor selected from the group consisting of tetrakis(dimethylamino)hafnium, and tetrakis(ethylmethylamino)hafnium;
wherein
at least one of the at least one organoaminosilane precursor and at least one of the at least one organoaminohafnium precursor have a same organoamino ligand;
less than 5 ppm of halide impurities; and
less than 5 ppm of metal impurities.

2. The composition of claim 1, wherein the composition comprises tetrakis(dimethylamino)silane and tetrakis(dimethylamino)hafnium.

3. The composition of claim 1, wherein the composition comprises tetrakis(ethylmethylamino)silane and tetrakis(ethylmethylamino)hafnium.

4. The composition of claim 1, wherein
the at least one organoaminosilane precursor ranges about 9.00 to about 11.00 wt. %; about 9.50 to about 10.50 wt. %, about 9.75% to about 10.25 wt. %, or about 9.90% to about 10.10 wt. %; and
the at least one organoaminohafnium precursor ranges about 89.00 to about 91.00 wt. %; about 89.50 to about 90.50 wt. %, about 89.75 to about 90.25 wt. %, or about 89.90 to about 90.90 wt. %.

5. The composition of claim 1, wherein the composition comprises 9.89 (±1) wt. % tetrakis(dimethylamino)silane and 90.11 (±1) wt. % tetrakis(dimethylamino)hafnium; or
the composition comprises 10 (±1) wt. % tetrakis(dimethylamino)silane and 90 wt. % (±1 wt. %) tetrakis(dimethylamino)hafnium.

6. The composition of claim 1, wherein the composition comprises 9.89 (±1) wt. % tetrakis(ethylmethylamino)silane and 90.11 (±1) wt. % tetrakis(ethylmethylamino)hafnium or
the composition comprises 10 (±1) wt. % tetrakis(ethylmethylamino)silane and 90 wt. % (±1 wt. %) tetrakis(ethylmethylamino)hafnium.

7. The composition of claim 1, wherein the composition comprises 10 ppm or less, or 5 ppm or less of chloride ions.

8. The composition of claim 1 further comprises (c) a solvent selected from the group consisting of ether, tertiary amine, alkyl hydrocarbon, aromatic hydrocarbon, siloxanes, tertiary aminoether, and combinations thereof.

9. The composition of claim 1 further comprises (c) a solvent selected from the group consisting of ether, tertiary amine, alkyl hydrocarbon, aromatic hydrocarbon, siloxanes, tertiary aminoether, and combinations thereof; and total weight percent of the at least one organoaminosilane precursor and the at least one organoaminohafnium precursor is from 0.01 to 90.99 wt. %, 10.00 to 90.00 wt. %, 20.00 to 80.00 wt. %, 30.00 to 70.00 wt. %, or 40.00 to 60.00 wt. %.

10. The composition of claim 1, wherein the at least one organoaminosilane precursor comprises tetrakis(dimethyamino)silane, the at least one organoaminohafnium precursor comprises tetrakis(dimethylamino)hafnium and weight percent (wt. %) ratio of tetrakis(dimethylamino)hafnium to tetrakis(dimethylamino)silane ranges from 7 to 13, 8 to 12, or 9 to 11.

11. A method to deposit a film comprising silicon, hafnium, and oxygen onto a substrate, comprising:
a) providing the substrate in a reactor;
b) introducing into the reactor the composition of any one of claims 1 to 10;
c) purging the reactor with a purge gas;
d) introducing an oxygen-containing source into the reactor; and
e) purging the reactor with the purge gas;
wherein
the oxygen-containing source is selected from the group consisting of an oxygen plasma, ozone, hydrogen peroxide, a water vapor, water vapor plasma, nitrogen oxide plasma, a carbon oxide plasma, and combinations thereof;
the purge gas selected from the group consisting of argon (Ar), nitrogen (N₂), helium (He), neon, hydrogen (H₂), and combinations thereof;
deposition process is selected from the group consisting of a thermal atomic layer deposition (ALD), plasma enhanced atomic layer deposition (PEALD) process, cyclic chemical vapor deposition, plasma enhanced cyclic chemical vapor deposition, and combination thereof;
the method is conducted at a temperature ranging from 100° C. to 350° C., 125° C. to 325° C., 150° C. to 325° C., 200° C. to 300° C., 220° C. to 300° C., or 230° C. to 300° C.; and
b) through e) are repeated until a desired thickness of film is deposited.

12. The method of claim 11, wherein the composition is delivered into the reactor via vaporization through direct liquid injection apparatus.

13. The method of claim 11, wherein the oxygen-containing source further comprises an inert gas selected from the group consisting of argon, helium, nitrogen, hydrogen, and combinations thereof.

14. A system to deposit a film comprising silicon, hafnium, and oxygen onto a substrate, comprising:
the substrate in a reactor; and
the composition of any one of claims 1 to 10;
wherein
the system is at a temperature ranging from 100° C. to 350° C., 125° C. to 325° C., 150° C. to 325° C., 200° C. to 300° C., 220° C. to 300° C., or 230° C. to 300° C.

15. A silicon doped hafnium oxide film suitable as ferroelectric materials deposited by using the composition of any one of claims 1 to 10 or the method of any one of claims 11 to 13.

16. The silicon doped hafnium oxide film of claim 15, wherein the silicon doped hafnium oxide film has a silicon doping level ranging from 2 to 6 mol. %, or 3.00 to 5.00 mol. %.

17. The silicon doped hafnium oxide film of claim 15, wherein the silicon doped hafnium oxide film has a silicon doping level ranging from 3.00 to 5.00 mol. %.

18. A vessel employing the composition of any one of claims 1 to 10.
